(19) United States
(12) Patent Application Publication
(10) Pub. No.: US 2016/0330059 A1
(43) Pub. Date: Nov. 10, 2016

(54) DISTRIBUTED PILOTS FOR SINGLE CARRIER TRANSMISSION

(71) Applicant: QUALCOMM Incorporated, San Diego, CA (US)

(72) Inventors: Alecsander Eitan, Haifa (IL); Amichai Sanderovich, Atlit (IL)

(21) Appl. No.: 15/147,435

(22) Filed: May 5, 2016

Related U.S. Application Data
(60) Provisional application No. 62/158,436, filed on May 7, 2015.

(51) Int. Cl. H04L 27/26; H03M 13/15; H04L 5/00; H04W 28/06; H04B 7/04

(52) U.S. Cl. CPC H04L 27/2613; H04W 28/065; H04B 7/0413; H04L 5/0048; H04L 27/2626; H04L 27/2647; H04L 27/2607; H03M 13/1505

(57) ABSTRACT

Certain aspects of the present disclosure provide methods and apparatuses for generating a frame for wireless transmission, wherein the frame comprises a payload including a plurality of blocks, each block comprising a data portion and a plurality of pilots distributed in the data portion. The distributed pilots may be used by a receiver receiving the frame to perform phase tracking during the data portions of the blocks to reduce phase noise.

### RELATED APPLICATION

This application claims priority under 35 U.S.C. §119(e) to U.S. Provisional Application No. 62/158,436 filed on May 7, 2015, the entire specification of which is incorporated herein by reference.

### FIELD

Certain aspects of the present disclosure generally relate to wireless communications and, more particularly, to distributed pilots for single carrier (SC) transmission.

### BACKGROUND

In order to address the issue of increasing bandwidth requirements demanded for wireless communications systems, different schemes are being developed. In some schemes, data is wirelessly transmitted at high data rates (e.g., several Gigabits/s) over one or more channels in the 60 GHz range.

### SUMMARY

Certain aspects of the present disclosure provide an apparatus for wireless communications. The apparatus comprises a processing system configured to generate a frame, wherein the frame comprises a payload including a plurality of blocks, each block comprising a data portion and a plurality of pilots distributed in the data portion. The apparatus also comprises an interface configured to output the frame for wireless transmission.

Certain aspects of the present disclosure provide a method for wireless communications. The method comprises generating a frame, wherein the frame comprises a payload including a plurality of blocks, each block comprising a data portion and a plurality of pilots distributed in the data portion. The method also comprises outputting the frame for wireless transmission.

Certain aspects of the present disclosure provide an apparatus for wireless communications. The apparatus comprises means for generating a frame, wherein the frame comprises a payload including a plurality of blocks, each block comprising a data portion and a plurality of pilots distributed in the data portion. The apparatus also comprises means for outputting the frame for wireless transmission.

Certain aspects of the present disclosure provide a computer-readable medium. The computer-readable medium comprises instructions stored thereon for generating a frame, wherein the frame comprises a payload including a plurality of blocks, each block comprising a data portion and a plurality of pilots distributed in the data portion. The computer-readable medium also comprises instructions stored thereon for outputting the frame for wireless transmission.

Certain aspects of the present disclosure provide a wireless node. The wireless node comprises at least one antenna, and a processing system configured to generate a frame, wherein the frame comprises a payload including a plurality of blocks, each block comprising a data portion and a plurality of pilots distributed in the data portion. The apparatus also comprises a transmitter configured to transmit, via the at least one antenna, the frame.

Certain aspects of the present disclosure provide an apparatus for wireless communications. The apparatus comprises an interface for receiving a signal comprising a frame, wherein the frame comprises a payload including a plurality of blocks, each block comprising a data portion and a plurality of pilots distributed in the data portion. The apparatus also comprises a processing system configured to determine a location of each of the plurality of pilots in one or more of the blocks, to measure a phase at each of the locations using the respective pilot, and to track phase changes in the received signal based on the measured phases.

Certain aspects of the present disclosure provide a method for wireless communications. The method comprises receiving a signal comprising a frame, wherein the frame comprises a payload including a plurality of blocks, each block comprising a data portion and a plurality of pilots distributed in the data portion. The method also comprises determining a location of each of the plurality of pilots in one or more of the blocks, measuring a phase at each of the locations using the respective pilot, and tracking phase changes in the received signal based on the measured phases.

Certain aspects of the present disclosure provide an apparatus for wireless communications. The apparatus comprises means for receiving a signal comprising a frame, wherein the frame comprises a payload including a plurality of blocks, each block comprising a data portion and a plurality of pilots distributed in the data portion. The apparatus also comprises means for determining a location of each of the plurality of pilots in one or more of the blocks, means for measuring a phase at each of the locations using the respective pilot, and means for tracking phase changes in the received signal based on the measured phases.

Certain aspects of the present disclosure provide a computer-readable medium. The computer-readable medium comprises instructions stored thereon for receiving a signal comprising a frame, wherein the frame comprises a payload including a plurality of blocks, each block comprising a data portion and a plurality of pilots distributed in the data portion. The computer-readable medium also comprises instructions stored thereon for determining a location of each of the plurality of pilots in one or more of the blocks, measuring a phase at each of the locations using the respective pilot, and tracking phase changes in the received signal based on the measured phases.

Certain aspects of the present disclosure provide a wireless node. The wireless node comprises at least one antenna, and a receiver configured to receive, via the at least one antenna, a signal comprising a frame, wherein the frame comprises a payload including a plurality of blocks, each block comprising a data portion and a plurality of pilots distributed in the data portion. The wireless node also comprises a processing system configured to determine a location of each of the plurality of pilots in one or more of the blocks, to measure a phase at each of the locations using the respective pilot, and to track phase changes in the received signal based on the measured phases.

### BRIEF DESCRIPTION OF THE DRAWINGS

FIG. 1 illustrates an exemplary wireless communication system in accordance with certain aspects of the present disclosure.

FIG. 2 is a block diagram of an exemplary access point and access terminal in accordance with certain aspects of the present disclosure.

FIG. 3 illustrates an exemplary frame structure in accordance with certain aspects of the present disclosure.

FIG. 4 illustrates an exemplary block structure in accordance with certain aspects of the present disclosure.

FIG. 5 illustrates another exemplary block structure in accordance with certain aspects of the present disclosure.

FIG. 6 illustrates yet another exemplary block structure in accordance with certain aspects of the present disclosure.

FIG. 7 illustrates still another exemplary block structure in accordance with certain aspects of the present disclosure.

FIG. 8 is a flowchart of a method for wireless communications in accordance with certain aspects of the present disclosure.

FIG. 9 is a flowchart of another method for wireless communications in accordance with certain aspects of the present disclosure.

FIG. 10 is a block diagram illustrating a device in accordance with certain aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

Although particular aspects are described herein, many variations and permutations of these aspects fall within the scope of the disclosure. Although some benefits and advantages of the preferred aspects are mentioned, the scope of the disclosure is not intended to be limited to particular benefits, uses, or objectives. Rather, aspects of the disclosure are intended to be broadly applicable to different wireless technologies, system configurations, networks, and transmission protocols, some of which are illustrated by way of example in the figures and in the following description of the preferred aspects. The detailed description and drawings are merely illustrative of the disclosure rather than limiting, the scope of the disclosure being defined by the appended claims and equivalents thereof.

The techniques described herein may be used for various broadband wireless communication systems, including communication systems that are based on an orthogonal multiplexing scheme. Examples of such communication systems include Spatial Division Multiple Access (SDMA), Time Division Multiple Access (TDMA), Orthogonal Frequency Division Multiple Access (OFDMA) systems, Single-Carrier Frequency Division Multiple Access (SC-FDMA) systems, and so forth. An SDMA system may utilize sufficiently different directions to simultaneously transmit data belonging to multiple access terminals. A TDMA system may allow multiple access terminals to share the same frequency channel by dividing the transmission signal into different time slots, each time slot being assigned to different access terminal. An OFDMA system utilizes orthogonal frequency division multiplexing (OFDM), which is a modulation technique that partitions the overall system bandwidth into multiple orthogonal sub-carriers. These sub-carriers may also be called tones, bins, etc. With OFDM, each sub-carrier may be independently modulated with data. An SC-FDMA system may utilize interleaved FDMA (IFDMA) to transmit on sub-carriers that are distributed across the system bandwidth, localized FDMA (LFDMA) to transmit on a block of adjacent sub-carriers, or enhanced FDMA (EFDMA) to transmit on multiple blocks of adjacent sub-carriers. In general, modulation symbols are sent in the frequency domain with OFDM and in the time domain with SC-FDMA.

The teachings herein may be incorporated into (e.g., implemented within or performed by) a variety of wired or wireless apparatuses (e.g., nodes). In some aspects, a wireless node implemented in accordance with the teachings herein may comprise an access point or an access terminal.

An access point (“AP”) may comprise, be implemented as, or known as a Node B, a Radio Network Controller (“RNC”), an evolved Node B (eNB), a Base Station Controller (“BSC”), a Base Transceiver Station (“BTS”), a Base Station (“BS”), a Transceiver Function (“TF”), a Radio Router, a Radio Transceiver, a Basic Service Set (“BSS”), an Extended Service Set (“ESS”), a Radio Base Station (“RBS”), or some other terminology.

An access terminal (“AT”) may comprise, be implemented as, or known as a subscriber station, a subscriber unit, a mobile station, a remote station, a remote terminal, a user terminal, a user agent, a user device, user equipment, a user station, or some other terminology. In some implementations, an access terminal may comprise a cellular telephone, a cordless telephone, a Session Initiation Protocol (“SIP”) phone, a wireless local loop (“WLL”) station, a personal digital assistant (“PDA”), a handheld device having wireless connection capability, a Station (“STA”), or some other suitable processing device connected to a wireless modem. Accordingly, one or more aspects taught herein may be incorporated into a phone (e.g., a cellular phone or smart phone), a computer (e.g., a laptop), a portable communication device, a portable computing device (e.g., a personal data assistant), an entertainment device (e.g., a music or video device, or a satellite radio), a global positioning system device, or any other suitable device that is configured to communicate via a wireless or wired medium. In some aspects, the node is a wireless node. Such wireless node may provide, for example, connectivity for or to a network (e.g., a wide area network such as the Internet or a cellular network) via a wired or wireless communication link.

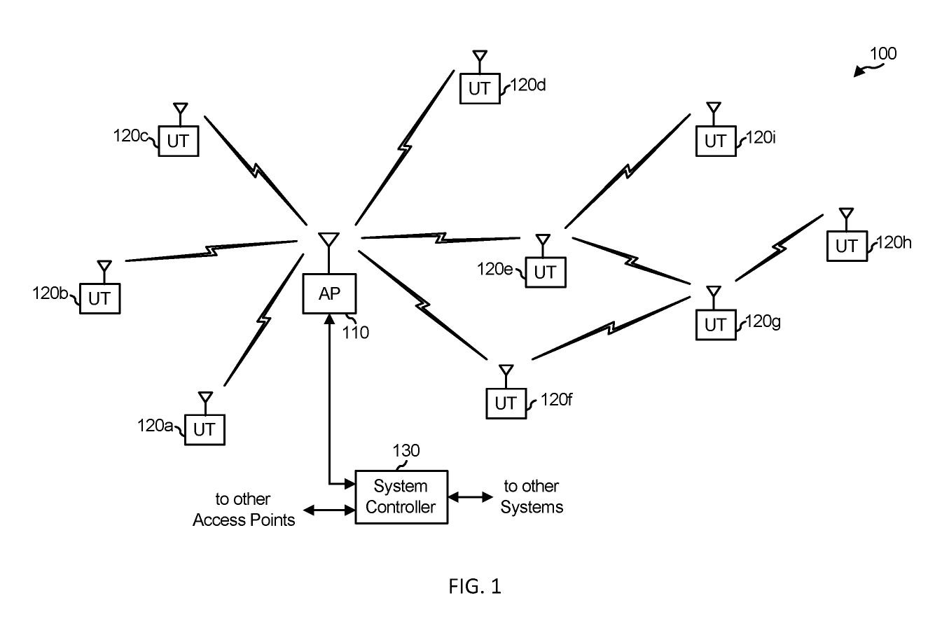

FIG. 1 illustrates an example of a wireless communication system 100 with access points and access terminals. For simplicity, only one access point 110 is shown in FIG. 1. An access point is generally a fixed station that communicates with the access terminals and may also be referred to as a base station or some other terminology. An access terminal may be fixed or mobile and may also be referred to as a mobile station, a wireless device or some other terminology. Access point 110 may communicate with one or more access terminals 120a-120i at any given moment on the downlink and uplink. The downlink (i.e., forward link) is the communication link from the access point to the access terminals, and the uplink (i.e., reverse link) is the communication link from the access terminals to the access point. An access terminal may also communicate peer-to-peer with another access terminal. A system controller 130 couples to and provides coordination and control for the access points.

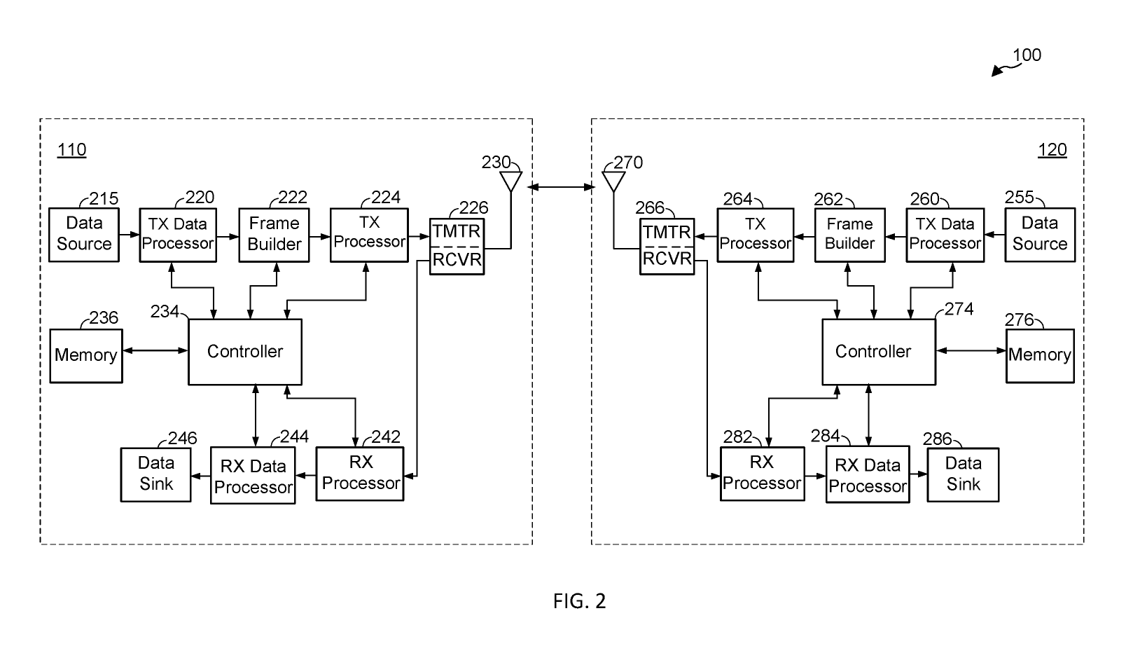

FIG. 2 illustrates a block diagram of an access point 110 and an access terminal 120 in the wireless communication system 100. The access point 110 is a transmitting entity for the downlink and a receiving entity for the uplink. The access terminal 120 is a transmitting entity for the uplink and a receiving entity for the downlink. As used herein, a “transmitting entity” is an independently operated apparatus or device capable of transmitting data via a wireless channel, and a “receiving entity” is an independently operated apparatus or device capable of receiving data via a wireless channel.

For transmitting data, the access point 110 comprises a transmit data processor 220, a frame builder 222, a transmit processor 224, a transceiver 226, and one or more antennas 230 (for simplicity one antenna is shown). The access point 110 also comprises a controller 234 for controlling operations of the access point 110, as discussed further below.

In operation, the transmit data processor 220 receives data (e.g., data bits) from a data source 215, and processes the data for transmission. For example, the transmit data processor 220 may encode the data (e.g., data bits) into encoded data, and modulate the encoded data into data symbols. The transmit data processor 220 may support different modulation and coding schemes (MCSs). For example, the transmit data processor 220 may encode the data (e.g., using low-density parity check (LDPC) encoding) at any one of a plurality of different coding rates. Also, the transmit data processor 220 may modulate the encoded data using any one of a plurality of different modulation schemes, including, but not limited to, BPSK, QPSK, 16QAM, 64QAM, 64APSK, 128APSK, 256QAM, and 256APSK. In certain aspects, the controller 234 may send a command to the transmit data processor 220 specifying which modulation and coding scheme (MCS) to use (e.g., based on channel conditions of the downlink), and the transmit data processor 220 may encode and modulate data from the data source 215 according to the specified MCS. It is to be appreciated that the transmit data processor 220 may perform additional processing on the data such as data scrambling, and/or other processing. The transmit data processor 220 outputs the data symbols to the frame builder 222.

The frame builder 222 constructs a frame (also referred to as a packet), and inserts the data symbols into a data payload of the frame. The frame may include a preamble, a header, and the data payload. The preamble may include a short training field (STF) sequence and a channel estimation (CE) sequence to assist the access terminal 120 in receiving the frame, as discussed further below. The header may include information related to the data in the payload such as the length of the data and the MCS used to encode and modulate the data. This information allows the access terminal 120 to demodulate and decode the data. The data in the payload may be divided among a plurality of blocks where each block may include a portion of the data and a guard interval (GI) to assist the receiver with phase tracking, as discussed further below. The frame builder 222 outputs the frame to the transmit processor 224.

The transmit processor 224 processes the frame for transmission on the downlink. For example, the transmit processor 224 may support different transmission modes such as an orthogonal frequency-division multiplexing (OFDM) transmission mode and a single-carrier (SC) transmission mode. In this example, the controller 234 may send a command to the transmit processor 224 specifying which transmission mode to use, and the transmit processor 224 may process the frame for transmission according to the specified transmission mode.

The transceiver 226 receives and processes (e.g., converts to analog, amplifies, filters, and frequency upconverts) the output of the transmit processor 224 for transmission via the one or more antennas 230. For example, the transceiver 226 may upconvert the output of the transmit processor 224 to a transmit signal have a frequency in the 60 GHz range.

In certain aspects, the transmit processor 224 may support multiple-output-multiple-input (MIMO) transmission. In these aspects, the access point 110 may include multiple antennas and multiple transceivers (e.g., one for each antenna). The transmit processor 224 may perform spatial processing on the incoming data symbols and provide a plurality of transmit symbol streams for the plurality of antennas. The transceivers receive and process (e.g., converts to analog, amplifies, filters, and frequency upconverts) the respective transmit symbol streams to generate transmit signals for transmission via the antennas.

For transmitting data, the access terminal 120 comprises a transmit data processor 260, a frame builder 262, a transmit processor 264, a transceiver 266, and one or more antennas 270 (for simplicity one antenna is shown). The access terminal 120 may transmit data to the access point 110 on the uplink, and/or transmit data to another access terminal (e.g., for peer-to-peer communication). The access terminal 120 also comprises a controller 274 for controlling operations of the access terminal 120, as discussed further below.

In operation, the transmit data processor 260 receives data (e.g., data bits) from a data source 255, and processes (e.g., encodes and modulates) the data for transmission. The transmit data processor 260 may support different MCSs. For example, the transmit data processor 260 may encode the data (e.g., using LDPC encoding) at any one of a plurality of different coding rates, and modulate the encoded data using any one of a plurality of different modulation schemes, including, but not limited to, BPSK, QPSK, 16QAM, 64QAM, 64APSK, 128APSK, 256QAM, and 256APSK. In certain aspects, the controller 274 may send a command to the transmit data processor 260 specifying which MCS to use (e.g., based on channel conditions of the uplink), and the transmit data processor 260 may encode and modulate data from the data source 255 according to the specified MCS. It is to be appreciated that the transmit data processor may perform additional processing on the data. The transmit data processor 260 outputs the data symbols to the frame builder 262.

The frame builder 262 constructs a frame, and inserts the received data symbols into a data payload of the frame. The frame may include a preamble, a header, and the data payload. The preamble may include an STF sequence and a CE sequence to assist the access point 110 and/or other access terminal in receiving the frame, as discussed further below. The header may include information related to the data in the payload such as the length of the data and the MCS used to encode and modulate the data. The data in the payload may be divided among a plurality of blocks where each block may include a portion of the data and a guard interval (GI) to assist the access point and/or other access terminal with phase tracking, as discussed further below. The frame builder 262 outputs the frame to the transmit processor 264.

The transmit processor 264 processes the frame for transmission. For example, the transmit processor 264 may support different transmission modes such as an OFDM transmission mode and an SC transmission mode. In this example, the controller 274 may send a command to the transmit processor 264 specifying which transmission mode to use, and the transmit processor 264 may process the frame for transmission according to the specified transmission mode.

The transceiver 266 receives and processes (e.g., converts to analog, amplifies, filters, and frequency upconverts) the output of the transmit processor 264 for transmission via the one or more antennas 270. For example, the transceiver 266 may upconvert the output of the transmit processor 264 to a transmit signal have a frequency in the 60 GHz range.

In certain aspects, the transmit processor 264 may support multiple-output-multiple-input (MIMO) transmission. In these aspects, the access terminal 120 may include multiple antennas and multiple transceivers (e.g., one for each antenna). The transmit processor 264 may perform spatial processing on the incoming data symbols and provide a plurality of transmit symbol streams for the plurality of antennas. The transceivers receive and process (e.g., converts to analog, amplifies, filters, and frequency upconverts) the respective transmit symbol streams to generate transmit signals for transmission via the antennas.

For receiving data, the access point 110 comprises a receive processor 242, and a receive data processor 244. In operation, the transceiver 226 receives a signal (e.g., from the access terminal 120), and processes (e.g., frequency downconverts, amplifies, filters and converts to digital) the received signal.

The receive processor 242 receives the output of the transceiver 226, and processes the output to recover data symbols. For example, the access point 110 may receive data (e.g., from the access terminal 120) in a frame, as discussed above. In this example, the receive processor 242 may detect the start of the frame using the STF sequence in the preamble of the frame. The receive processor 242 may also use the STF for automatic gain control (AGC) adjustment. The receive processor 242 may also perform channel estimation (e.g., using the CE sequence in the preamble of the frame) and perform channel equalization on the received signal based on the channel estimation. Further, the receive processor 242 may estimate phase using the guard intervals (GIs) in the payload, and reduce phase noise in the received signal based on the estimated phase, as discussed further below. The phase noise may be due to noise from a local oscillator in the access terminal 120 and/or noise from a local oscillator in the access point 110 used for frequency conversion. The phase noise may also include noise from the channel. The receive processor 242 may also recover information (e.g., MCS scheme) from the header of the frame, and send the information to the controller 234. After performing channel equalization and/or phase noise reduction, the receive processor 242 may recover data symbols from the frame, and output the recovered data symbols to the receive data processor 244 for further processing, as discussed further below.

The receive data processor 244 receives the data symbols from the receive processor 242 and an indication of the corresponding MSC scheme from the controller 234. The receive data processor 244 demodulates and decodes the data symbols to recover the data according to the indicated MSC scheme, and outputs the recovered data (e.g., data bits) to a data sink 246 for storage and/or further processing.

As discussed above, the access terminal 120 may transmit data using an OFDM transmission mode or a SC transmission mode. In this case, the receive processor 242 may process the receive signal according to the selected transmission mode. Also, as discussed above, the transmit processor 264 may support multiple-output-multiple-input (MIMO) transmission. In this case, the access point 110 may include multiple antennas and multiple transceivers (e.g., one for each antenna). Each transceiver receives and processes (e.g., frequency downcoverts, amplifies, filters, converts to digital) the signal from the respective antenna. The receive processor 242 may perform spatial processing on the outputs of the transceivers to recover the data symbols.

For receiving data, the access terminal 120 comprises a receive processor 282, and a receive data processor 284. In operation, the transceiver 266 receives a signal (e.g., from the access point 110 or another access terminal), and processes (e.g., frequency downconverts, amplifies, filters and converts to digital) the received signal.

The receive processor 282 receives the output of the transceiver 266, and processes the output to recover data symbols. For example, the access terminal 120 may receive data (e.g., from the access point 110 or another access terminal) in a frame, as discussed above. In this example, the receive processor 282 may detect the start of the frame using the STF sequence in the preamble of the frame. The receive processor 282 may also perform channel estimation (e.g., using the CE sequence in the preamble of the frame) and perform channel equalization on the received signal based on the channel estimation. Further, the receive processor 282 may estimate phase using the guard intervals (GIs) in the payload, and reduce phase noise in the received signal based on the estimated phase, as discussed further below. The receive processor 282 may also recover information (e.g., MCS scheme) from the header of the frame, and send the information to the controller 274. After performing channel equalization and/or phase noise reduction, the receive processor 282 may recover data symbols from the frame, and output the recovered data symbols to the receive data processor 284 for further processing, as discussed further below.

The receive data processor 284 receives the data symbols from the receive processor 282 and an indication of the corresponding MSC scheme from the controller 274. The receive data processor 284 demodulates and decodes the data symbols to recover the data according to the indicated MSC scheme, and outputs the recovered data (e.g., data bits) to a data sink 286 for storage and/or further processing.

As discussed above, the access point 110 or another access terminal may transmit data using an OFDM transmission mode or a SC transmission mode. In this case, the receive processor 282 may process the receive signal according to the selected transmission mode. Also, as discussed above, the transmit processor 224 may support multiple-output-multiple-input (MIMO) transmission. In this case, the access terminal 120 may include multiple antennas and multiple transceivers (e.g., one for each antenna). Each transceiver receives and processes (e.g., frequency downcoverts, amplifies, filters, converts to digital) the signal from the respective antenna. The receive processor 282 may perform spatial processing on the outputs of the transceivers to recover the data symbols.

As shown in FIG. 2, the access point 110 also comprises a memory 236 coupled to the controller 234. The memory 236 may store instructions that, when executed by the controller 234, cause the controller 234 to perform one or more of the operations described herein. Similarly, the access terminal 120 also comprises a memory 276 coupled to the controller 274. The memory 276 may store instructions that, when executed by the controller 274, cause the controller 274 to perform the one or more of the operations described herein.

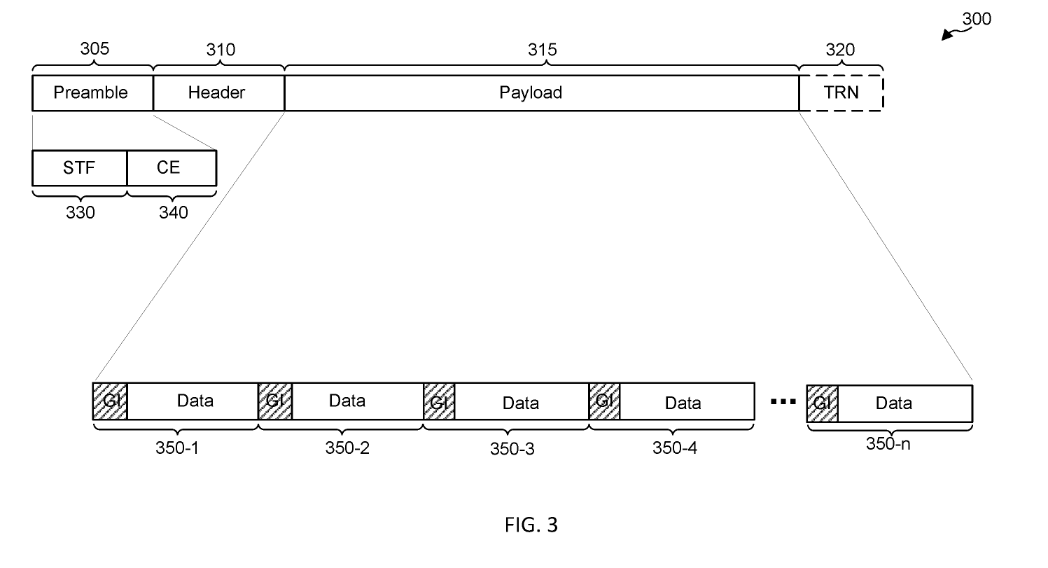

FIG. 3 shows an exemplary frame structure 300 in accordance with certain aspects of the present disclosure. The frame 300 comprises a preamble 305, a header 310, a payload 315, and an optional beamforming training field 320. It is to be appreciated that the frame 300 may comprise additional fields. The preamble 305 may comprise a short training field (STF) sequence 330 and a channel estimation (CE) sequence 340. The STF sequence may assist a receiver in performing automatic gain control (AGC), time synchronization, and frequency offset cancelation for accurately receiving the rest of the frame and possibly subsequent frames. For example, the STF sequence may include a plurality of Golay sequences (Ga₁₂₈) and a negative Golay sequence (−Ga₁₂₈) to signify the end of the STF sequence. It is to be appreciated that the STF sequence 330 is not limited to this example, and that other Golay sequences may be used.

The CE sequence 340 may assist the receiver in performing channel estimation. In this regard, the CE sequence 340 may comprise Golay sequences. For example, for the SC transmission mode, the CE sequence may include a Gu₅₁₂ sequence (consisting of the following concatenated Golay sequences (−Gb₁₂₈, −Ga₁₂₈, Gb₁₂₈, −Ga₁₂₈) followed by a Gv₅₁₂ sequence (consisting of the following concatenated Golay sequences (−Gb₁₂₈, Ga₁₂₈, −Gb₁₂₈, −Ga₁₂₈), and ending with a Gv₁₂₈ sequence (same as −Gb₁₂₈). For the OFDM transmission mode, the CE sequence may include a Gv₅₁₂ sequence followed by a Gu₅₁₂ sequence, and ending with a Gv₁₂₈ sequence. It is to be appreciated that the CE sequence 340 is not limited to the above examples, and that other Golay sequences may be used for the CE sequence 340.

The header 310 includes various information about the frame. For example, the header 310 may include a modulation and coding scheme (MCS) field to indicate which one of a plurality of MCSs is used to encode and module the data in the payload 315. This information allows the receiver to demodulate and decode the data in frame in accordance with the indicated MCS. The header 310 may also include a length field indicating the length of the payload 315. Additionally, the header 310 may include a packet type field to indicate whether the optional beam forming field 320 is included. The beam forming field 320 may include beam-forming information if beam steering is used at the transmitter to direct the transmitted signal to the receiver. It is to be appreciated that the header 310 may include additional information.

The payload 315 is divided into a plurality of blocks 350-1 to 350-n. Each block 350-1 to 350-n comprises a guard interval (GI) (shaded in FIG. 3) and a portion of the data (labeled “Data” in FIG. 3) in the payload 315. The GI in each block 350-1 to 310-n comprises a reference that is known a priori by the receiver for assisting the receiver with phase tracking. The known reference allows the receiver to estimate phase in the received signal, and reduce the phase noise based on the estimated phase. In certain aspects, the GI in each block 350-1 to 350-n may comprise a Golay sequence known by the receiver. The GI may also be used to perform frequency domain equalization (FDE) at the receiver. The data portion of each block 350-1 to 350-n is modulated in accordance with the modulation scheme indicated in the header 310 for the data.

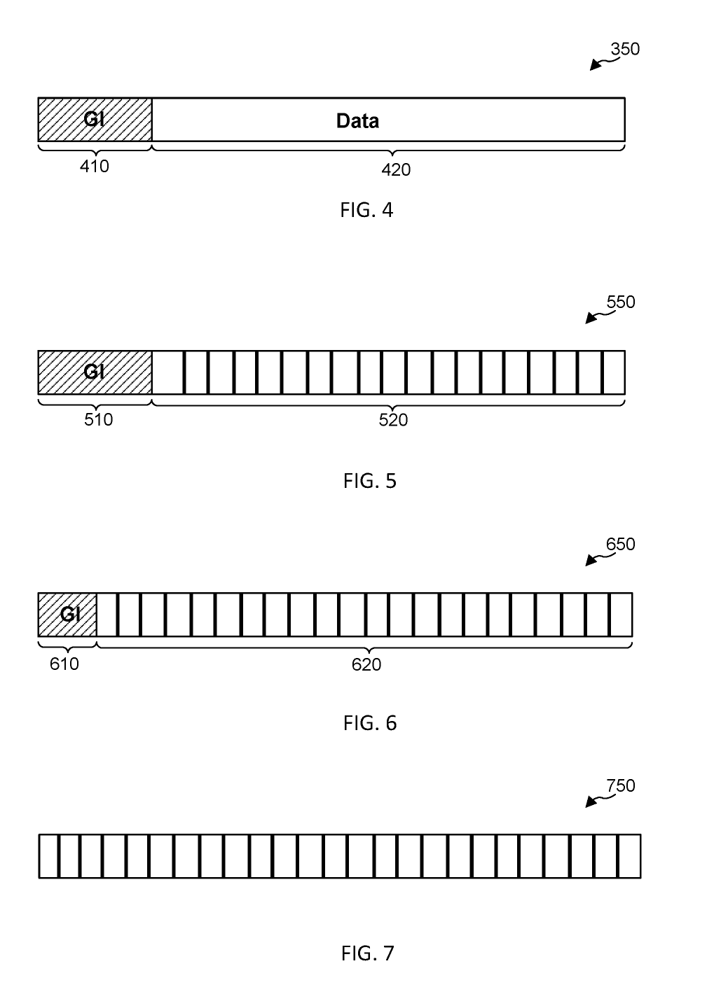

FIG. 4 shows a close-up view of one of the blocks 350. In one example, the GI 410 may comprise a 64-symbol Golay sequence (denoted “Ga₆₄”) and the data portion 420 may comprise 448 data symbols for a total block length of 512 symbols according to the IEEE 802.11ad standard for WLAN in the 60 GHz band. It is to be appreciated that the present disclosure is not limited to this example.

At 60 GHz, phase noise is one of the main contributors to receiver noise. Currently, SC mode is used due to superior peak to average power ratio (PAPR) relative to OFDM. In SC mode, channel equalization is a big challenge. The presence of the periodic GIs (shown in FIGS. 3 and 4) allows for frequency domain equalization (FDE) that is a very effective method with relatively low complexity. However, this method can track phase only at the GIs. As a result, the receiver may not be able to track phase changes during the data portions of the blocks, which impact and limit receiver performance.

Some receiver use decision feedback equalization (DFE) methods to improve equalization and track phase changes. However, at high transmission rates (e.g., 1.76 G symbols per second), it may be almost impossible to use DFE due to the complexity involved and the low delay required to implement DFE (in IEEE 802.11ad receivers, most stages are pipelined to allow reasonable implementation).

The IEEE 802.11 ay standard, which is the successor to the IEEE 802.11ad standard, will extend the SC mode specified in the IEEE 802.11ad standard to channel bonding (CB) with higher symbol rates and higher constellations. As a result, it may be very difficult to implement DFE in the IEEE 802.11ay standard.

To address the above problems, a plurality of pilots may be distributed (interspersed) in the data portion of each block in accordance with certain aspects of the present disclosure. The pilots allow the receiver to track phase changes during the data portions of the blocks, and therefore reduce phase noise during the data portions of the blocks. Further, pilot-based phase tracking avoids the complexity involved in implementing DFE. As used herein, the term “pilot” is understood to cover any reference that is known a priori by the receiver.

FIG. 5 shows an exemplary block structure 550 according to certain aspects of the present disclosure. The block 550 includes a GI 510, and a data portion 520 comprising data symbols. The GI 510 may include a Golay sequence. The block 550 also includes a plurality of pilots (shown as dark bands in the data portion 520) distributed (interspersed) throughout the data portion 520. In certain aspects, the pilots may be approximately evenly distributed in the data portion 520. It is to be appreciated that the spacing between pilots does not have to be exactly even. For instance, the spacing may vary by one or two symbols. Each pilot may comprise a reference that is known a priori by the receiver to assist the receiver with phase tracking. The block 550 allows the receiver to track the phase of the received signal during the data portion 520, and therefore reduce phase noise along the block 550.

In certain aspects, the block structure 550 may be based on a modification of an existing block structure with a GI and a data portion. For example, the GI of the original block may be kept and pilots may be interspersed in the data portion. In this example, the size of the data portion may be kept the same by reducing the number of data symbols. Thus, the number of data symbols in the data portion may be reduced to keep the total block length the same. The pilots may be any reference known by the receiver.

FIG. 6 shows another exemplary block structure 650 according to certain aspects of the present disclosure. The block 650 includes a GI 610, a data portion 620 comprising data symbols, and a plurality of pilots (shown as dark bands in the data portion 620) distributed (interspersed) throughout the data portion 620.

In certain aspects, the block structure 650 may be based on a modification of an existing block structure with a GI and a data portion. For example, the original GI may be split into a first portion (e.g., first half) and a second portion (e.g., remaining half). The first portion may stay in the GI 610 and the second portion may be distributed (interspersed) in the data portion 620 for the pilots (e.g., one symbol per pilot). The pilots may be approximately evenly spaced in the data portion. By doing this, the data size and block size are kept the same as the original block structure, which may reduce the impact on other parameters of the data frame format. Also, since the GI is kept (length does not matter) and the same overall block length is kept, FDE possibility is preserved.

For example, the block structure 650 may be based on a modification of the block structure in the IEEE 802.11ad standard. In this example, the 64-symbol Golay sequence in the original GI may be split into a first portion (e.g., first 32 Golay symbols) and a second portion (e.g., remaining 32 Golay symbols), in which the first portion stays in the GI 610 and the Golay symbols in the second portion are distributed among the pilots in the data portion 620 (e.g., on Golay symbol per pilot). Thus, the sum of the symbols in the GI 610 and pilots equals 64 symbols, which is the length of the GI in the IEEE 802.11ad standard.

In certain aspects, the block 650 structure may comprise a Golay sequence that is split between the GI 610 and the pilots in the data portion 620. A first portion of the Golay sequence is in the GI 610, and a second portion of the Golay sequence is distributed among the pilots in the data portion 620. In these aspects, each pilot may comprise one or more symbols of the second portion of the Golay sequence. For example, each pilot may comprise a single symbol of the second portion of the Golay sequence. The pilots may be approximately evenly distributed in the data portion 620. It is to be appreciated that the spacing between pilots does not have to be exactly even. For instance, the spacing may vary by one or two symbols.

In certain aspects, the first portion of the Golay sequence may comprise a first half of the Golay sequence and the second portion of the Golay sequence may comprise the remaining half of the Golay sequence. In general, the first portion of the Golay sequence may comprise the first N symbols of the Golay sequence and the second portion of the Golay sequence may comprise the remaining M symbols of the Golay sequence, where N and M are integers and the sum of N and M is approximately equal to the number of symbols in the Golay sequence. Each pilot may comprise one or more symbols of the remaining M symbols of the Golay sequence.

The block structure 550 in FIG. 5 or the block structure 650 in FIG. 6 may be used to implement each block in the payload 315 of the frame. In this case, each block 550 or 650 may comprise a portion of the data symbols in the payload 315.

Examples of block structures with distributed pilots will now be discussed in accordance with aspects of the present disclosure.

In a first example, the basic format of the block is the same as in the IEEE 802.11ad standard. The block may be transmitted on one channel. In this example, the GI length may be 32 symbols and the block length may be 512. Also, in this example, 32 pilots may be distributed in the data portion with an average pilot spacing of 14.5758 symbols. Exemplary locations for the pilots may be as follows (GI starts at location 0): 46, 60, 75, 89, 104, 118, 133, 148, 162, 177, 191, 206, 220, 235, 250, 264, 279, 293, 308, 323, 337, 352, 366, 381, 395, 410, 425, 439, 454, 468, 483 and 497. In one example, a 64-symbol Golay sequence may be used, in which the first 32 Golay symbols are used for the GI, and the remaining 32 Golay symbols are distributed among the pilots (e.g., one symbol for each pilot). However, it is to be appreciated that the present disclosure is not limited to this example, and that other references known by the receiver may be used for the pilots.

In a second example, the block may be transmitted using channel bonding on two channels. Channel boding is discussed further below. In this example, the GI length may be 64 symbols and the block length may be 1024. Also, in this example, 64 pilots may be distributed in the data portion with an average pilot spacing of 13.7846 symbols. Exemplary locations for the pilots may be as follows (GI starts at location 0): 78, 93, 107, 122, 137, 152, 166, 181, 196, 211, 226, 240, 255, 270, 285, 300, 314, 329, 344, 359, 373, 388, 403, 418, 433, 447, 462, 477, 492, 507, 521, 536, 551, 566, 580, 595, 610, 625, 640, 654, 669, 684, 699, 714, 728, 743, 758, 773, 787, 802, 817, 832, 847, 861, 876, 891, 906, 921, 935, 950, 965, 980, 994 and 1009. In one example, a 128-symbol Golay sequence may be used, in which the first 64 Golay symbols are used for the GI, and the remaining 64 Golay symbols are distributed among the pilots (e.g., one symbol for each pilot). However, it is to be appreciated that the present disclosure is not limited to this example, and that other references known by the receiver may be used for the pilots.

In a third example, the block may be transmitted using channel bonding on three channels. In this example, the GI length may be 96 symbols and the block length may be 1536. Also, in this example, 96 pilots may be distributed in the data portion with an average pilot spacing of 13.8557 symbols. Exemplary locations for the pilots may be as follows (GI starts at location 0): 110, 125, 140, 154, 169, 184, 199, 214, 229 244, 258, 273, 288, 303, 318, 333, 348, 362, 377, 392, 407, 422, 437, 452, 466, 481, 496, 511, 526, 541, 556, 570, 585, 600, 615, 630, 645, 660, 674, 689, 704, 719, 734, 749, 764, 778, 793, 808, 823, 838, 853, 867, 882, 897, 912, 927, 942, 957, 971, 986, 1001, 1016, 1031, 1046, 1061, 1075, 1090, 1105, 1120, 1135, 1150, 1165, 1179, 1194, 1209, 1224, 1239, 1254, 1269, 1283, 1298, 1313, 1328, 1343, 1358, 1373, 1387, 1402, 1417, 1432, 1447, 1462, 1477, 1491, 1506 and 1521. In one example, a 192-symbol Golay sequence may be used, in which the first 96 Golay symbols are used for the GI, and the remaining 96 Golay symbols are distributed among the pilots (e.g., one symbol for each pilot). However, it is to be appreciated that the present disclosure is not limited to this example, and that other references known by the receiver may be used for the pilots.

In a fourth example, the block may be transmitted using channel bonding on four channels. In this example, the GI length may be 128 symbols and the block length may be 2018. Also, in this example, 128 pilots may be distributed in the data portion with an average pilot spacing of 13.8915 symbols. Exemplary locations for the pilots may be as follows (GI starts at location 0): 142, 157, 172, 187, 201, 216, 231, 246, 261, 276, 291, 306, 321, 335, 350, 365, 380, 395, 410, 425, 440, 455, 470, 484, 499, 514, 529, 544, 559, 574, 589, 604, 618, 633, 648, 663, 678, 693, 708, 723, 738, 752, 767, 782, 797, 812, 827, 842, 857, 872, 886, 901, 916, 931, 946, 961, 976, 991, 1006, 1020, 1035, 1050, 1065, 1080, 1095, 1110, 1125, 1140, 1155, 1169, 1184, 1199, 1214, 1229, 1244, 1259, 1274, 1289, 1303, 1318, 1333, 1348, 1363, 1378, 1393, 1408, 1423, 1437, 1452, 1467, 1482, 1497, 1512, 1527, 1542, 1557, 1571, 1586, 1601, 1616, 1631, 1646, 1661, 1676, 1691, 1705, 1720, 1735, 1750, 1765, 1780, 1795, 1810, 1825, 1840, 1854, 1869, 1884, 1899, 1914, 1929, 1944, 1959, 1974, 1988, 2003, 2018 and 2033. In one example, a 256-symbol Golay sequence may be used, in which the first 128 Golay symbols are used for the GI, and the remaining 128 Golay symbols are distributed among the pilots (e.g., one symbol for each pilot). However, it is to be appreciated that the present disclosure is not limited to this example, and that other references known by the receiver may be used for the pilots.

Distributed pilots are applicable even for a block that does not include a GI. In this regard, FIG. 7 shows an exemplary block 750 comprising data symbols and a plurality of pilots (shown as dark bands in the block 750) distributed (interspersed) throughout the block 750. The pilots may be approximately evenly distributed in the block. It is to be appreciated that the spacing between pilots does not have to be exactly even. Each pilot may comprise a reference that is known a priori by the receiver to assist the receiver with phase tracking. The distributed pilots allow the receiver to track the phase along the block 750, and therefore reduce phase noise along the block 750.

In certain aspects, the average space between adjacent pilots in a block may be between 10 and 120 symbols (e.g., between 10 and 120 data symbols). This spacing may be sufficient to allow the receiver to track phase changes for high symbol rates (e.g., used in the IEEE 802.11ay standard). It is to be appreciated that the present disclosure is not limited to the above examples, and that other space sizes may be used.

As discussed above, blocks according to certain aspects of the present disclosure may be transmitted on two or more channels bonded together using channel bonding. Channel bonding is provided in the IEEE 802.11ay standard to increase throughput. In certain aspects, the payload comprising the blocks may be transmitted on two or more channels using channel bonding. The header may also be transmitted on the two or more channels using channel bonding. Alternatively, the header may be redundantly transmitted on each of the channels according to the legacy IEEE 802.11ad standard. Also, the preamble may be transmitted on the two or more channels using channel bonding. Alternatively, the preamble may be redundantly transmitted on each of the channels according to the legacy IEEE 802.11ad standard. In one example, the frame may comprise a first STF field redundantly transmitted on each of the channels according to the legacy IEEE 802.11ad standard, and a second STF field transmitted on the two or more channels using channel bonding. Similarly, the frame may comprise a first CE field redundantly transmitted on each of the channels according to the legacy IEEE 802.11ad standard, and a second CE field transmitted on the two or more channels using channel bonding. Additional details regarding channel bonding can be found, for example, in U.S. Provisional Application No. 62/147,479 filed on Apr. 14, 2015, the entire specification on which is incorporated herein by reference.

As discussed above, distributed pilots in a block allow the receiver to track phase changes along the block to reduce phase noise. In this regard, the receiver may know the locations of the pilots in a block a priori. For example, the receiver may store, in a memory, block format information including the pilot locations in a block. This information allows the receiver to locate the pilots in a received block. The receiver may measure a phase of the received signal at each pilot location using the respective pilot, and track phase changes in the received signal along block based on the measured phases to reduce phase noise. The above operations may be performed by receive processor 242 or 282. Thus, the distributed pilots allow the receiver to perform pilot-based phase tracking along the block.

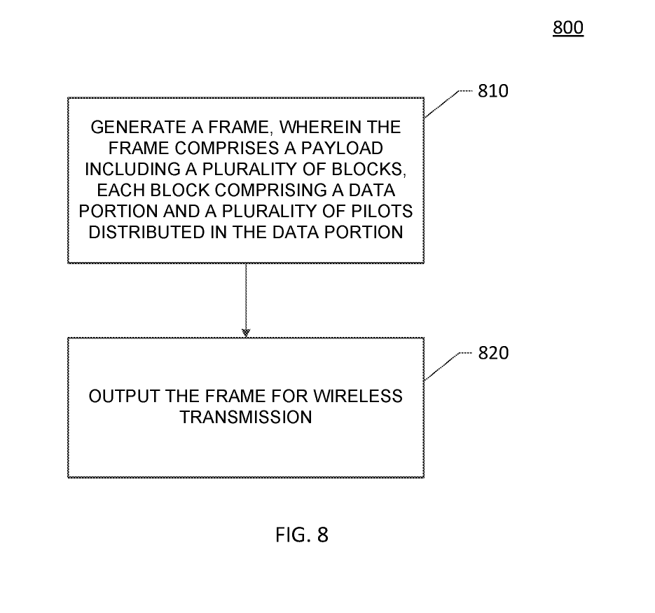

FIG. 8 illustrates example operations 800 for wireless communication in accordance with certain aspects of the present disclosure. The operations 800 may be performed, for example, by a wireless node (e.g., the access point 110 or access terminal 120).

At 810, a frame is generated, wherein the frame comprises a payload including a plurality of blocks, each block comprising a data portion and a plurality of pilots distributed in the data portion. For example, the frame may be generated by frame builder 222 or 262. Each block may have, for example, the block structure 550, 650 or 750 shown in FIG. 5, 6 or 7 or other block structure with distributed pilots.

At 820, the frame is output for wireless transmission. For example, the frame may be output via an interface to an RF front end (e.g., transceiver 226 or 266) for wireless transmission.

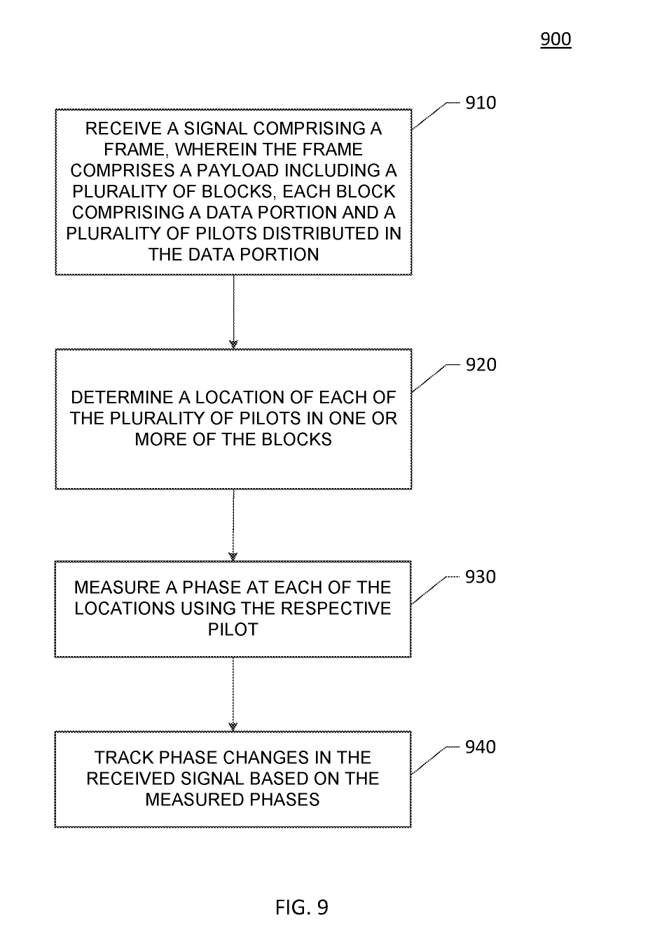

FIG. 9 illustrates example operations 900 for wireless communication in accordance with certain aspects of the present disclosure. The operations 900 may be performed, for example, by a wireless node (e.g., the access point 110 or access terminal 120).

At 910, a signal comprising a frame is received, wherein the frame comprises a payload including a plurality of blocks, each block comprising a data portion and a plurality of pilots distributed in the data portion. Each block may have, for example, the block structure 550, 650 or 750 shown in FIG. 5, 6 or 7 or other block structure with distributed pilots.

At 920, a location of each of the plurality of pilots in one or more of the blocks is determined. For example, the location of each of the plurality of pilots may be determined using block format information stored at a wireless node, wherein the block format information includes the pilot locations in a block. At 930, a phase at each of the locations is measured using the respective pilot. At 940, phase changes in the received signal are tracked based on the measured phases.

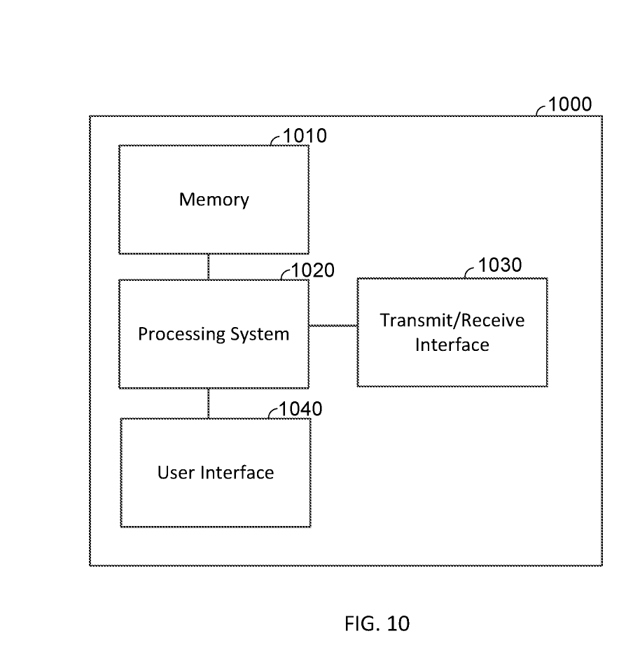

FIG. 10 illustrates an example device 1000 according to certain aspects of the present disclosure. The device 1000 may be configured to operate in an access point (e.g., access point 110) or an access terminal (e.g., access terminal 120) and to perform one or more of the operations described herein. The device 1000 includes a processing system 1020, and a memory 1010 coupled to the processing system 1020. The memory may store instructions that, when executed by the processing system 1020, cause the processing system 1020 to perform one or more of the operations described herein. Exemplary implementations of the processing system 1020 are provided below. The device 1000 also comprises a transmit/receiver interface 1030 coupled to the processing system 1020. The interface 1030 (e.g., interface bus) may be configured to interface the processing system 1020 to a radio frequency (RF) front end (e.g., transceiver 226 or 266), as discussed further below.

In certain aspects, the processing system 1020 may include a transmit data processor (e.g., transmit data processor 220 or 260), a frame builder (e.g., frame builder 222 or 262), a transmit processor (e.g., transmit processor 224 or 264) and/or a controller (e.g., controller 234 or 274) for performing one or more of the operations described herein. In these aspects, the processing system 1020 may generate a frame and output the frame to an RF front end (e.g., transceiver 226 or 266) via the interface 1030 for wireless transmission (e.g., to an access point 110 or an access terminal 120).

In certain aspects, the processing system 1020 may include a receive processor (e.g., receive processor 242 or 282), a receive data processor (e.g., receive data processor 244 or 284) and/or a controller (e.g., controller 234 or 274) for performing one or more of the operations described herein. In these aspects, the processing system 1020 may receive a frame from an RF front end (e.g., transceiver 226 or 266) via the interface 1030 and process the frame according to any one or more of the aspects discussed above.

In the case of an access terminal 120, the device 1000 may include a user interface 1040 coupled to the processing system 1020. The user interface 1040 may be configured to receive data from a user (e.g., via keypad, mouse, joystick, etc.) and provide the data to the processing system 1020. The user interface 1040 may also be configured to output data from the processing system 1020 to the user (e.g., via a display, speaker, etc.). In this case, the data may undergo additional processing before being output to the user. In the case of an access point 110, the user interface may be omitted.

Examples of means for generating a frame, wherein the frame comprises a payload including a plurality of blocks, each block comprising a data portion and a plurality of pilots distributed in the data portion, include the frame builder 222 or 262, and the processing system 1020. Examples of means for outputting the frame for wireless transmission include the transmit processor 224 or 264, the transceiver 226 or 266, and the transmit/receive interface 1030. Examples of means for receiving data symbols include the frame builder 222 or 262, and the processing system 1020. Examples of means for distributing the received data symbols among the data portions of the blocks include the frame builder 222 or 262, and the processing system 1020. Examples of means for determining a modulation and coding scheme (MCS) used to encode and modulate data into the data symbols include the controller 234 or 274, the frame builder 222 or 262, and the processing system 1020. Examples of means for inserting an indication of the determined MCS in the header include the frame builder 222 or 262, and the processing system 1020.

Examples of means for receiving a signal comprising a frame, wherein the frame comprises a payload including a plurality of blocks, each block comprising a data portion and a plurality of pilots distributed in the data portion, include the transceiver 226 or 266, the receive processor 242 or 282, and the transmit/receive interface 1030. Examples of means for determining a location of each of the plurality of pilots in one or more of the blocks include the receive processor 242 or 282, the controller 234 or 274, and the processing system 1020. Examples of means for measuring a phase at each of the locations using the respective pilot include the receive processor 242 or 282, the controller 234 or 274, and the processing system 1020. Examples of means for tracking phase changes in the received signal based on the measured phases include the receive processor 242 or 282, the controller 234 or 274, and the processing system 1020. Examples of means for determining the location of each of the plurality of pilots using block format information stored at the apparatus include the controller 234 or 274, and the processing system 1020. Examples of means for recovering data symbols from the data portions of the blocks include the receive processor 242 or 282, and the processing system 1020. Examples of means for demodulating the data symbols based on the indicated modulation scheme include the receive data processor 244 or 284, and the processing system 1020.

The various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, circuits described in connection with the present disclosure (e.g., processing system 1020) may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium (e.g., memory 1010) that is known in the art. Some examples of storage media that may be used include random access memory (RAM), read only memory (ROM), flash memory, EPROM memory, EEPROM memory, registers, a hard disk, a removable disk, a CD-ROM and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the PHY layer. In the case of an access terminal 120 (see FIG. 1), a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and general processing, including the execution of software stored on the machine-readable media. The processor may be implemented with one or more general-purpose and/or special-purpose processors. Examples include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the wireless node, all which may be accessed by the processor through the bus interface. Alternatively, or in addition, the machine-readable media, or any portion thereof, may be integrated into the processor, such as the case may be with cache and/or general register files.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC (Application Specific Integrated Circuit) with the processor, the bus interface, the user interface in the case of an access terminal), supporting circuitry, and at least a portion of the machine-readable media integrated into a single chip, or with one or more FPGAs (Field Programmable Gate Arrays), PLDs (Programmable Logic Devices), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module.

If implemented in software, the functions may be stored or transmitted over as one or more instructions or code on a computer-readable medium. Computer-readable media include both computer storage media and communication media including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc where disks usually reproduce data magnetically, while discs reproduce data optically with lasers. Thus, in some aspects computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented herein. For example, such a computer program product may comprise a computer-readable medium having instructions stored (and/or encoded) thereon, the instructions being executable by one or more processors to perform the operations described herein. For certain aspects, the computer program product may include packaging material.

Further, it should be appreciated that modules and/or other appropriate means for performing the methods and techniques described herein can be downloaded and/or otherwise obtained by an access terminal and/or base station as applicable. For example, such a device can be coupled to a server to facilitate the transfer of means for performing the methods described herein. Alternatively, various methods described herein can be provided via storage means (e.g., RAM, ROM, a physical storage medium such as a compact disc (CD) or floppy disk, etc.), such that an access terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the methods and apparatus described above without departing from the scope of the claims.

1. An apparatus for wireless communications, comprising:
a processing system configured to generate a frame, wherein the frame comprises a payload including a plurality of blocks, each block comprising a data portion and a plurality of pilots distributed in the data portion; and
an interface configured to output the frame for wireless transmission.

2. The apparatus of claim 1, wherein each of the plurality of pilots comprises one or more pilot symbols.

3. The apparatus of claim 1, wherein an average space between adjacent pilots in the data portion of at least one of the blocks is between 10 and 120 symbols.

4. The apparatus of claim 1, wherein the pilots in the data portion of at least one of the blocks are approximately evenly distributed in the data portion.

5. The apparatus of claim 1, wherein each of the plurality of pilots in the data portion of at least one of the blocks comprises a single pilot symbol.

6. The apparatus of claim 1, wherein the processing system is further configured to insert a guard interval in each of the plurality of blocks.

7. The apparatus of claim 6, wherein the guard interval of at least one of the blocks comprises a first portion of a Golay sequence, and a second portion of the Golay sequence being distributed among the pilots in the data portion.

8. The apparatus of claim 7, wherein the Golay sequence comprises at least one of a 64-symbol Golay sequence, a 128-symbol Golay sequence, or a 256-symbol Golay sequence.

9. The apparatus of claim 1, wherein the processing system is configured to receive data symbols, and to distribute the received data symbols among the data portions of the blocks.

10. The apparatus of claim 9, wherein the frame further comprises a header, and the processing system is configured to determine a modulation and coding scheme (MCS) used to encode and modulate data into the data symbols, and to insert an indication of the determined MCS in the header.

11. A method for wireless communications, comprising:
generating a frame, wherein the frame comprises a payload including a plurality of blocks, each block comprising a data portion and a plurality of pilots distributed in the data portion; and
outputting the frame for wireless transmission.

12. The method of claim 11, wherein each of the plurality of pilots comprises one or more pilot symbols.

13. The method of claim 11, wherein an average space between adjacent pilots in the data portion of at least one of the blocks is between 10 and 120 symbols.

14. The method of claim 11, wherein the pilots in the data portion of at least one of the blocks are approximately evenly distributed in the data portion.

15. The method of claim 11, wherein each of the plurality of pilots in the data portion of at least one of the blocks comprises a single pilot symbol.

16. The method of claim 11, further comprising inserting a guard interval in each of the plurality of blocks.

17. The method of claim 16, wherein the guard interval of at least one of the blocks comprises a first portion of a Golay sequence, and a second portion of the Golay sequence being distributed among the pilots in the data portion.

18. The method of claim 17, wherein the Golay sequence comprises at least one of a 64-symbol Golay sequence, a 128-symbol Golay sequence, or a 256-symbol Golay sequence.

19. The method of claim 11, further comprising:
receiving data symbols; and
distributing the received data symbols among the data portions of the blocks.

20. The method of claim 19, wherein the frame further comprises a header, and the method further comprises:
determining a modulation and coding scheme (MCS) used to encode and modulate data into the data symbols; and
inserting an indication of the determined MCS in the header.

21.-32. (canceled)

33. An apparatus for wireless communications, comprising:
an interface for receiving a signal comprising a frame, wherein the frame comprises a payload including a plurality of blocks, each block comprising a data portion and a plurality of pilots distributed in the data portion; and
a processing system configured to determine a location of each of the plurality of pilots in one or more of the blocks, to measure a phase at each of the locations using the respective pilot, and to track phase changes in the received signal based on the measured phases.

34. The apparatus of claim 33, wherein the processing system is configured to determine the location of each of the plurality of pilots using block format information stored at the apparatus.

35.-40. (canceled)

41. The apparatus of claim 33, wherein the processing system is further configured to recover data symbols from the data portions of the blocks.

42. The apparatus of claim 41, wherein the frame further comprises a header indicating a modulation scheme, and the processing system is further configured to demodulate the data symbols based on the indicated modulation scheme.

43.-64. (canceled)
